(19) United States
(12) Patent Application Publication
(10) Pub. No.: US 2010/0006954 A1
(43) Pub. Date: Jan. 14, 2010

(54) TRANSISTOR DEVICE

(76) Inventors: Tsai-Yu Huang, Taipei County (TW); Shin-Yu Nieh, Taipei City (TW); Hui-Lan Chang, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/241,096

(22) Filed: Sep. 30, 2008

(30) Foreign Application Priority Data
Jul. 9, 2008 (TW) 097125941

(51) Int. Cl. H01L 29/78

(52) U.S. Cl. 257/410; 257/E29.255

(57) ABSTRACT

A transistor device includes a semiconductor substrate, a source doping region and a drain doping region in the semiconductor, a channel region between the source doping region and the drain doping region, a gate stack on the channel region, wherein the gate stack includes an amorphous interfacial layer, a crystalline metal oxide gate dielectric layer and a gate conductor.

### BACKGROUND OF THE INVENTION

1. Field of the Invention

The present invention relates generally to semiconductor devices, and more specifically to a metal-oxide-semiconductor field effect transistor (MOSFET) and fabrication method thereof.

2. Description of the Prior Art

With a trend towards scaling town the CMOS size, conventional methods, which are used to achieve optimization, such as reducing thickness of the gate dielectric layer, for example the thickness of silicon dioxide layer, have faced problems such as leakage current due to tunneling effect.

In order to keep progression to next generation, high-k dielectric materials have been introduced to replace the conventional silicon dioxide to be the gate dielectric layer because it decreases physical limit thickness effectively, reduces leakage current, and obtains equivalent capacitor in an identical equivalent oxide thickness (EOT).

It is known in the art that high-k dielectric materials include metal oxides and metal silicates. Transition metal oxides such as hafnium dioxide and hafnium silicate are employed in the industry to be high-k gate dielectric materials with dielectric constants greater than that of silicon dioxide. However, the deposition of metal oxides to form high-k polycrystalline structures has a disadvantage of introducing trapping sites within the dielectric itself. These trapping sites adversely affect the electrical behavior of the transistor. For example, trapping sites can affect the threshold voltage and long term reliability of a semiconductor device. To avoid the aforesaid trap formation and degradation of transistor performance, an amorphous metal oxide such as amorphous hafnium silicate to form the metal oxide dielectric is typically employed.

To ensure that the hafnium silicate film is in an amorphous phase, it is known that the silicon content of the hafnium silicate film must exceed 50 at. % in order to avoid the transformation of the hafnium silicate film from the amorphous phase into crystalline phase during the subsequent thermal processes such as RTP process for activating source or drain dopants. However, the dielectric constant of the amorphous hafnium silicate film (k˜25) is not high enough. In some circumstances, it may require that the dielectric constant of the hafnium silicate film is higher than 25, even higher than 30, which the conventional amorphous hafnium silicate film is not able to provide.

### SUMMARY OF THE INVENTION

It is one objective of the present invention to provide an improved MOS transistor device in order to solve the above-mentioned prior art shortcomings.

According to the first embodiment, a transistor device includes a semiconductor substrate; a source doping region and a drain doping region in the semiconductor substrate; a gate channel region in the semiconductor substrate between the source doping region and a drain doping region; and a gate electrode structure disposed directly on the gate channel region, wherein the gate electrode structure comprises an amorphous interfacial layer, a crystalline metal oxide gate dielectric layer on the amorphous interfacial layer, and a gate conductive layer on the crystalline metal oxide gate dielectric layer.

According to the second embodiment, a transistor device includes a semiconductor substrate; a source doping region and a drain doping region in the semiconductor substrate; a gate channel region in the semiconductor substrate between the source doping region and a drain doping region; and a gate electrode structure disposed directly on the gate channel region, wherein the gate electrode structure comprises an amorphous interfacial layer on the semiconductor substrate, a metal oxide gate dielectric layer on the amorphous interfacial layer, and a gate conductive layer on the metal oxide gate dielectric layer, wherein the metal oxide gate dielectric layer comprises amorphous hafnium silicate and crystalline hafnium silicate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, cross-sectional diagram showing an MOSFET device in accordance with the first preferred embodiment of this invention.

FIG. 2 is a schematic, cross-sectional diagram showing an MOSFET device in accordance with the second preferred embodiment of this invention.

### DETAILED DESCRIPTION

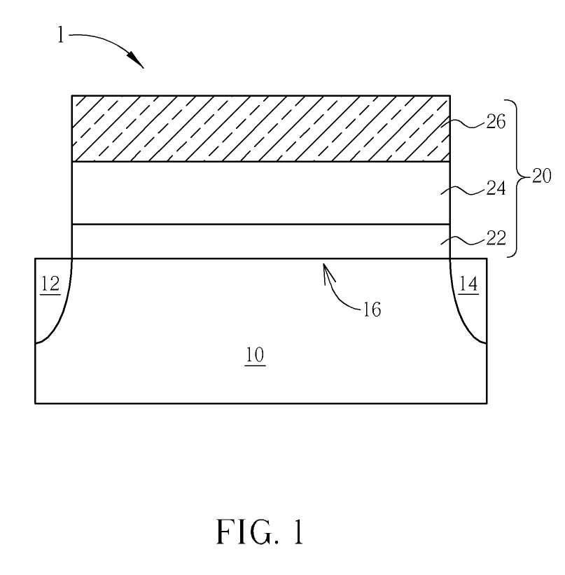

FIG. 1 is a schematic, cross-sectional diagram showing an MOSFET device 1 in accordance with the first preferred embodiment of this invention. As shown in FIG. 1, the MOSFET device 1 comprises a semiconductor substrate 10 such as silicon substrate, a source doping region 12 and a drain doping region 14 formed in the semiconductor substrate 10. A gate channel region 16 is defined between the source doping region 12 and the drain doping region 14. The MOSFET device 1 further comprises a gate electrode structure 20 disposed directly on the gate channel region 16.

According to the first preferred embodiment of this invention, the gate electrode structure 20 comprises an amorphous interfacial layer 22, a crystalline metal oxide gate dielectric layer 24 on the amorphous interfacial layer 22, and a gate conductive layer 26 on the crystalline metal oxide gate dielectric layer 24. The gate conductive layer 26 may include polysilicon or metals such as titanium nitride or tantalum nitride. The amorphous interfacial layer 22 may include amorphous silicon dioxide. Preferably, the amorphous interfacial layer 22 is a high-quality silicon dioxide formed by UVRF oxidation methods. Besides, the amorphous interfacial layer 22 may include nitrogen doped silicon oxide, preferably, nitrogen doped silicon oxide formed by decoupled plasma nitridation (DPN) methods. Of course, the amorphous interfacial layer 22 may be formed by atomic layer deposition (ALD) or UVRF methods. According to this invention, the thickness of the amorphous interfacial layer 22 is less than 5 angstroms.

According to the first preferred embodiment of this invention, the crystalline metal oxide gate dielectric layer 24 comprises tetragonal or cubic phase hafnium silicate Hf₁₀ₓSiₓO_{y}, wherein x ranges between 0.05 and 0.30. According to the first preferred embodiment of this invention, the hafnium content of the crystalline metal oxide gate dielectric layer 24 ranges between 70 at. % and 90 at. % and the silicon content of the crystalline metal oxide gate dielectric layer 24 ranges between 5 at. % and 30 at. %. The thickness of the crystalline metal oxide gate dielectric layer 24 preferably ranges between 5 angstroms and 90 angstroms. According to the first preferred embodiment of this invention, the crystalline metal oxide gate dielectric layer 24 has a dielectric constant that is equal to or greater than 39. According to this invention, the crystalline metal oxide gate dielectric layer 24 may be Hf₁₋ₓAlₓO_{y}, wherein Al may be replaced with rare earth elements such as lanthanum.

For example, multiple ALD cycles may be performed to deposit hafnium oxide (0.6 angstroms per ALD cycle) on the amorphous interfacial layer 22. Typically, each of the aforesaid ALD cycles includes four sequential stages: (1) flowing hafnium-containing organic metal precursor such as TEMA-Hf into the reactor for a period of time to adsorb the organic metal precursor on the surface of the substrate; (2) purging the excess organic metal precursor out of the reactor using inert gas such as argon; (3) flowing ozone into the reactor to react the ozone with the organic metal precursor adsorbed on the substrate; and (4) purging the reactor again with inert gas such as argon.

Thereafter, multiple ALD cycles are performed to deposit silicon atoms on the hafnium oxide. Likewise, each ALD cycle includes four sequential stages: (1) flowing silicon-containing organic metal precursor such as 3-DMAS or 4-DMAS into the reactor for a period of time to adsorb the organic metal precursor on the surface of the substrate; (2) purging the excess organic metal precursor out of the reactor using inert gas such as argon; (3) flowing ozone into the reactor to react the ozone with the organic metal precursor adsorbed on the substrate; and (4) purging the reactor again with inert gas such as argon.

It is understood that in addition to the aforesaid ALD methods, the present invention crystalline metal oxide gate dielectric layer 24 may be formed by other suitable methods such as physical vapor deposition (PVD), sputtering, chemical vapor deposition (CVD) or metal organic CVD (MOCVD).

Since the hafnium content ranges between 70 at. % and 90 at. % and the silicon content ranges between 5 at. % and 30 at. % according to this invention, the hafnium silicate can be readily transformed from amorphous phase to tetragonal or cubic crystalline phase merely using subsequent thermal processes such as RTP for activating source or drain dopants. However, it is understood that an additional thermal anneal process may be carried out to ensure that all the amorphous hafnium silicate are transformed to tetragonal or cubic crystalline phase. The aforesaid additional thermal anneal process may be performed at a high temperature of 700° C.-1000° C. for a time period of about 30 seconds.

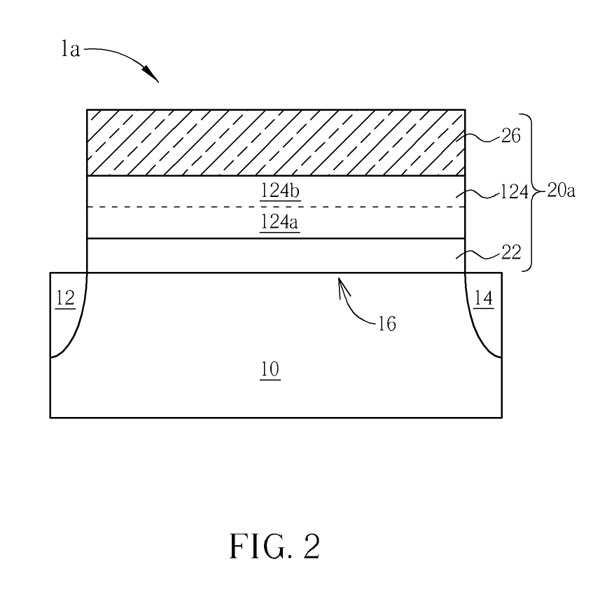

FIG. 2 is a schematic, cross-sectional diagram showing an MOSFET device 1a in accordance with the second preferred embodiment of this invention. As shown in FIG. 2, the MOSFET device 1a comprises a semiconductor substrate 10 such as silicon substrate, a source doping region 12 and a drain doping region 14 formed in the semiconductor substrate 10. A gate channel region 16 is defined between the source doping region 12 and the drain doping region 14. The MOSFET device 1 further comprises a gate electrode structure 20a disposed directly on the gate channel region 16.

According to the second preferred embodiment of this invention, the gate electrode structure 20a comprises an amorphous interfacial layer 22, a metal oxide gate dielectric layer 124 on the amorphous interfacial layer 22, and a gate conductive layer 26 on the metal oxide gate dielectric layer 124. The gate conductive layer 26 may include polysilicon or metals such as titanium nitride or tantalum nitride. The amorphous interfacial layer 22 may include amorphous silicon dioxide. Preferably, the amorphous interfacial layer 22 is a high-quality silicon dioxide formed by UVRF oxidation methods. Besides, the amorphous interfacial layer 22 may include nitrogen doped silicon oxide, preferably, nitrogen doped silicon oxide formed by decoupled plasma nitridation (DPN) methods. The amorphous interfacial layer 22 may be formed by atomic layer deposition (ALD) or UVRF methods.

According to the second preferred embodiment of this invention, the metal oxide gate dielectric layer 124 comprises amorphous hafnium silicate 124a and tetragonal or cubic phase hafnium silicate 124b expressed by Hf₁₋ₓSiₓO_{y}, wherein x ranges between 0.05 and 0.30. The silicon content of the amorphous hafnium silicate 124a is greater than 50 at. %, for example, 50 at. %-60 at. %. The hafnium content of the tetragonal or cubic phase hafnium silicate 124b ranges between 70 at. % and 90 at. % and the silicon content of the tetragonal or cubic phase hafnium silicate 124b ranges between 5 at. % and 30 at. %.

Those skilled in the art will readily observe that numerous modifications and alterations of the device and method may be made while retaining the teachings of the invention.

What is claimed is:

1. A transistor device, comprising:
a semiconductor substrate;
a source doping region and a drain doping region in the semiconductor substrate;
a gate channel region located between the source doping region and the drain doping region; and
a gate electrode structure disposed directly on the gate channel region, wherein the gate electrode structure comprises an amorphous interfacial layer, a crystalline metal oxide gate dielectric layer on the amorphous interfacial layer, and a gate conductive layer on the crystalline metal oxide gate dielectric layer.

2. The transistor device according to claim 1, wherein the amorphous interfacial layer comprises amorphous silicon dioxide.

3. The transistor device according to claim 2, wherein the amorphous interfacial layer comprises nitrogen doped silicon oxide.

4. The transistor device according to claim 1, wherein the amorphous interfacial layer has a thickness less than 5 angstroms.

5. The transistor device according to claim 1, wherein the crystalline metal oxide gate dielectric layer comprises tetragonal phase hafnium silicate.

6. The transistor device according to claim 1, wherein the crystalline metal oxide gate dielectric layer comprises cubic phase hafnium silicate.

7. The transistor device according to claim 6, wherein hafnium content of the crystalline metal oxide gate dielectric layer ranges between 70 at. % and 90 at. % and silicon content of the crystalline metal oxide gate dielectric layer ranges between 5 at. % and 30 at. %.

8. The transistor device according to claim 1, wherein the crystalline metal oxide gate dielectric layer has a thickness ranging between 5 angstroms and 90 angstroms.

9. A transistor device, comprising:
a semiconductor substrate;
a source doping region and a drain doping region in the semiconductor substrate;
a gate channel region located between the source doping region and the drain doping region; and
a gate electrode structure disposed directly on the gate channel region, wherein the gate electrode structure comprises an amorphous interfacial layer on the semiconductor substrate, a metal oxide gate dielectric layer on the amorphous interfacial layer, and a gate conductive layer on the metal oxide gate dielectric layer, wherein the metal oxide gate dielectric layer comprises amorphous hafnium silicate and crystalline hafnium silicate.

10. The transistor device according to claim 9, wherein the crystalline hafnium silicate has a tetragonal phase.

11. The transistor device according to claim 9, wherein the crystalline hafnium silicate has a cubic phase.

12. The transistor device according to claim 9, wherein hafnium content of the crystalline hafnium silicate ranges between 70 at. % and 90 at. % and silicon content of the crystalline hafnium silicate ranges between 5 at. % and 30 at. %.

13. The transistor device according to claim 9, wherein silicon content of the amorphous hafnium silicate is greater than 50 at. %.

14. The transistor device according to claim 9, wherein the amorphous interfacial layer comprises amorphous silicon dioxide.

15. The transistor device according to claim 9, wherein the amorphous interfacial layer comprises nitrogen doped silicon oxide.

16. The transistor device according to claim 9, wherein the amorphous interfacial layer has a thickness of less than 5 angstroms.

17. The transistor device according to claim 9, wherein the metal oxide gate dielectric layer has a thickness ranging between 5 angstroms and 90 angstroms.
